(19) United States
(12) Patent Application Publication
(10) Pub. No.: US 2026/0305314 A1
(43) Pub. Date: Oct. 1, 2026

(54) SEMICONDUCTOR DEVICE INCLUDING METAL WIRING LAYER

(71) Applicant: Samsung Electronics Co., Ltd, Suwon-si (KR)

(72) Inventors: Sunguk Jang, Suwon-si (KR); Woojin Lee, Suwon-si (KR); Donghyun Ko, Suwon-si (KR); Sungjoo An, Suwon-si (KR); Jongsun Yoon, Suwon-si (KR); Hangyeol Choi, Suwon-si (KR)

(73) Assignee: Samsung Electronics Co., Ltd, Suwon-si (KR)

(21) Appl. No.: 19/535,688

(22) Filed: Feb. 10, 2026

(30) Foreign Application Priority Data
Mar. 28, 2025 (KR) 10-2025-0040475

(51) Int. Cl. H10W 20/47; H10W 20/42

(52) U.S. Cl. CPC H10W 20/47; H10W 20/42

(57) ABSTRACT

A semiconductor device includes a substrate, a metal wiring layer disposed above the substrate, a lower insulating structure disposed on the substrate and in contact with the metal wiring layer, an upper insulating structure disposed on the lower insulating structure, and a metal via disposed on the metal wiring layer and connected to the metal wiring layer, wherein the upper insulating structure extends outward from both side surfaces of the lower insulating structure, and a side surface of the upper insulating structure has a negative slope from a lower surface of the upper insulating structure.

### CROSS-REFERENCE TO RELATED APPLICATIONS

This present application claims priority to and the benefit under 35 U.S.C. § 119(a)-(d) of Korean Patent Application No. 10-2025-0040475, filed on Mar. 28, 2025, in the Korean Intellectual Property Office, the entire disclosure of which is incorporated herein by reference.

### FIELD

The disclosed concepts relate to a semiconductor device, and more particularly, to a semiconductor device including a metal wiring layer.

### BACKGROUND

With the development of electronic technology, down-scaling of semiconductor devices has been rapidly occurring. Accordingly, the line widths and pitches of metal wiring layers in semiconductor devices are also becoming smaller. With the trend toward smaller line widths and pitches of metal wiring layers, there is a need to improve the electrical reliability of the metal wiring layers.

### SUMMARY

According to aspects of the disclosed concepts, there is provided a semiconductor device including a substrate, a metal wiring layer disposed above the substrate, a lower insulating structure disposed on the substrate and in contact with the metal wiring layer, an upper insulating structure disposed on the lower insulating structure, and a metal via disposed on the metal wiring layer and connected to the metal wiring layer, wherein the upper insulating structure extends outward from both side surfaces of the lower insulating structure, and a side surface of the upper insulating structure has a negative slope from a lower surface of the upper insulating structure.

According to r aspects of the disclosed concepts, there is provided a semiconductor device including a substrate, a metal wiring layer disposed above the substrate, a lower insulating structure disposed on the substrate and in contact with the metal wiring layer, an upper insulating structure disposed on the lower insulating structure, and a metal via disposed on the metal wiring layer and connected to the metal wiring layer, wherein the upper insulating structure includes a first upper insulating layer disposed on the lower insulating structure and a second upper insulating layer disposed on the first upper insulating layer, the first upper insulating layer has a quadrangular shape of which side surfaces extend outward from both side surfaces of the lower insulating structure, and the second upper insulating layer has a tapered shape of which a side surface has a negative slope from a lower surface of the upper insulating structure.

According to aspects of the disclosed concepts, there is provided a semiconductor device including a substrate, a first etch stop layer disposed on the substrate, a metal wiring layer disposed on the first etch stop layer, a lower insulating structure passing through the first etch stop layer and disposed on the substrate while being in contact with a side surface of the metal wiring layer, an upper insulating structure disposed on the lower insulating structure, a second etch stop layer covering a surface of the upper insulating structure and an upper surface of the metal wiring layer, and a metal via passing through the second etch stop layer and disposed on the metal wiring layer, the metal via including a conductive liner and a conductive layer filling an inner space of the conductive liner, wherein the upper insulating structure includes a first upper insulating layer disposed on the lower insulating structure and a second upper insulating layer disposed on the first upper insulating layer, the first upper insulating layer has a quadrangular shape of which side surfaces extend outward from both side surfaces of the lower insulating structure, and the second upper insulating layer has a tapered shape of which a side surface has a negative slope from a lower surface of the upper insulating structure.

According to aspects of the disclosed concepts, there is provided a method of manufacturing a semiconductor device, the method including forming a metal wiring layer and a lower insulating structure on a substrate, forming an inhibitor on the metal wiring layer, forming an upper insulating structure on the lower insulating structure by using the inhibitor, partially removing a side surface of the upper insulating structure so that the side surface of the upper insulating structure has a negative slope, forming an etch stop layer and an interlayer insulating layer covering the upper insulating structure, and forming a metal via passing through the etch stop layer and the interlayer insulating layer.

In embodiments, the upper insulating structure may extend outward from side surfaces of the lower insulating structure.

In embodiments, a horizontal length of the upper insulating structure may be about 1.0 times to about 1.5 times a horizontal length of the lower insulating structure.

In embodiments, a horizontal length of the upper insulating structure may be about 1.0 times to about 1.5 times a vertical height of the upper insulating structure.

In embodiments, the forming of the upper insulating structure may include forming a first upper insulating layer on the lower insulating structure and forming a second upper insulating layer on the first upper insulating layer.

In embodiments, the first upper insulating layer and the second upper insulating layer may each include AlO, ZrO, HfO, SiO₂, AlSiO, or a combination thereof.

In embodiments, the first upper insulating layer may include a different material from a material of the second upper insulating layer.

In embodiments, the partial removing of the side surface of the upper insulating structure may include partially removing the side surface of the second upper insulating layer.

In embodiments, the forming of the upper insulating structure may include forming the upper insulating structure that is provided as a single layer including AlO, ZrO, HfO, SiO₂, AlSiO, or a combination thereof.

In embodiments, the lower insulating structure may include an air gap.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor device according to embodiments;

FIG. 2 is an enlarged cross-sectional view of region EX1 of FIG. 1;

FIG. 3 is a cross-sectional view illustrating a semiconductor device according to embodiments;

FIG. 4 is an enlarged cross-sectional view of region EX2 of FIG. 3;

FIG. 5 is a cross-sectional view illustrating a semiconductor device according to embodiments;

FIG. 6 is an enlarged cross-sectional view of region EX3 of FIG. 5;

FIG. 7 is a cross-sectional view illustrating a semiconductor device according to embodiments;

FIG. 8 is an enlarged cross-sectional view of region EX4 of FIG. 7; and

FIGS. 9 to 15 are cross-sectional views illustrating a method of manufacturing the semiconductor device, according to embodiments.

### DETAILED DESCRIPTION

Hereinafter, embodiments of the inventive concept are described in detail with reference to the accompanying drawings. The same reference numerals are given to the same elements in the drawings, and repeated descriptions thereof are omitted.

The disclosed concepts provide a semiconductor device having a structure capable of improving electrical reliability of metal wiring layers.

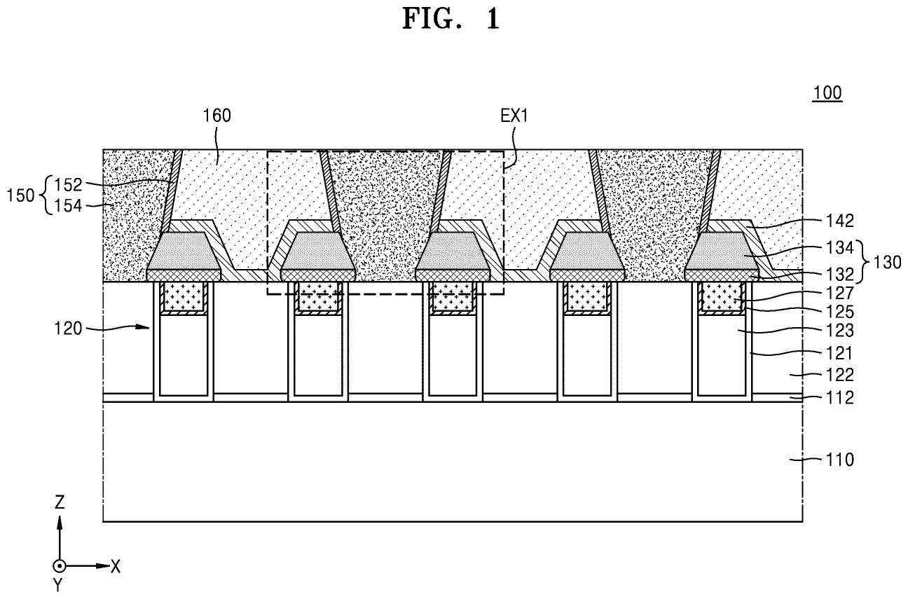

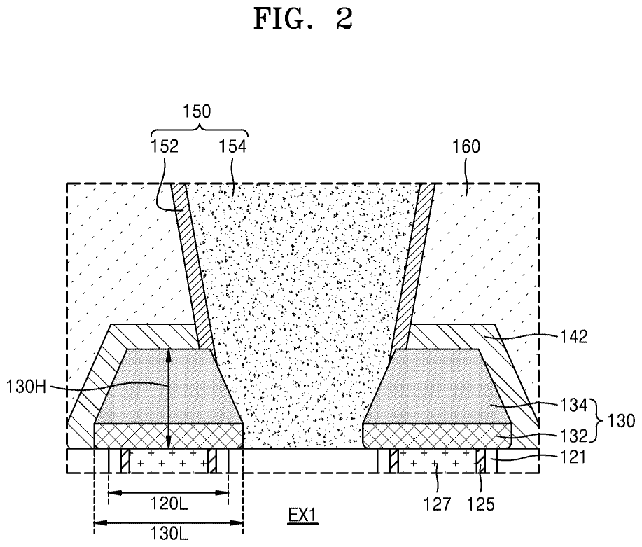

FIG. 1 is a cross-sectional view illustrating a semiconductor device 100 according to embodiments. FIG. 2 is an enlarged cross-sectional view of region EX1 of FIG. 1.

Referring to FIGS. 1 and 2, the semiconductor device 100 may include a substrate 110, a metal wiring layer 122 above the substrate 110, and a metal via 150 disposed on the metal wiring layer 122.

The semiconductor device 100 may represent, for example, a semiconductor device included in volatile memory or non-volatile memory. The volatile memory may include, for example, dynamic random-access memory (DRAM) and static random-access memory (SRAM), and the non-volatile memory may include, for example, read only memory (ROM), phase-change random access memory (PRAM), magnetic random-access memory (MRAM), resistive random-access memory (ReRAM), ferroelectric random-access memory (FeRAM), and flash memory.

The substrate 110 may include silicon, for example, single crystalline silicon, polycrystalline silicon, or amorphous silicon. In embodiments, the substrate 110 may include at least one selected from a group consisting of Ge, SiGe, SiC, GaAs, InAs, and InP. In embodiments, the substrate 110 may include a conductive region. The conductive region may include, for example, an impurity-doped well, an impurity-doped structure, or a conductive layer. The substrate 110 may include circuit elements (not shown), such as a gate structure, an impurity region, and a contact plug.

A first etch stop layer 112 may be disposed on the substrate 110. The first etch stop layer 112 may include a silicon nitride layer, a carbon-doped silicon nitride layer, or a carbon-doped silicon oxynitride layer. In embodiments, the first etch stop layer 112 may include an insulating metal oxide layer, an insulating metal nitride layer, or a combination thereof. For example, the first etch stop layer 112 may include an aluminum oxide layer (an AlO layer), an aluminum nitride layer (an AlN layer), or a combination thereof.

A lower insulating structure 120 may pass through the first etch stop layer 112 in a vertical direction (a Z direction) and be disposed on the substrate 110. The lower insulating structure 120 may include a first insulating liner 121, a first lower insulating layer 123, a second insulating liner 125, and a second lower insulating layer 127. The first insulating liner 121 may be in contact with the upper surface of the substrate 110. The first lower insulating layer 123 may fill the inner space of the first insulating liner 121. The second insulating liner 125 may be disposed on the first lower insulating layer 123 and in contact with the inner wall of the first insulating liner 121. The second lower insulating layer 127 may fill the inner space of the second insulating liner 125. In embodiments, the upper surface of the first insulating liner 121, the upper surface of the second insulating liner 125, and the upper surface of the second lower insulating layer 127 may be coplanar with each other.

In embodiments, the first insulating liner 121 and the second insulating liner 125 may each include, but are not limited to, silicon oxide, silicon oxynitride, silicon nitride, a low-k material having a lower dielectric constant than silicon oxide, or a combination thereof.

In embodiments, the first lower insulating layer 123 and the second lower insulating layer 127 may each include, but are not limited to, silicon oxide, silicon oxynitride, silicon nitride, a low-k material having a lower dielectric constant than silicon oxide, or a combination thereof.

In embodiments, the first lower insulating layer 123 may include an air gap. That is, the first lower insulating layer 123 may contain air.

The metal wiring layer 122 may be disposed above the substrate 110. The upper surface of the metal wiring layer 122 may be coplanar with the upper surface of the lower insulating structure 120. The metal wiring layer 122 may be in contact with the lower insulating structure 120 on both sides of the metal wiring layer 122. In embodiments, the metal wiring layer 122 may be configured to be electrically connected to a conductive region formed in the substrate 110. In some embodiments, the metal wiring layer 122 may be configured to be connected to circuit elements (not shown) formed in the substrate 110. The metal wiring layer 122 may include, for example, Cu, W, Mo, Ru, Co, Al, or a combination thereof.

An upper insulating structure 130 may be disposed on the lower insulating structure 120. The upper insulating structure 130 may include a first upper insulating layer 132 and a second upper insulating layer 134.

The first upper insulating layer 132 may be in contact with the upper surface of the lower insulating structure 120. The first upper insulating layer 132 may cover the upper surface of the lower insulating structure 120 and may cover the upper surface of part of the metal wiring layer 122, which is adjacent to the lower insulating structure 120. The first upper insulating layer 132 may have a quadrangular shape of which both side surfaces are not inclined. The two side surfaces of the first upper insulating layer 132 may respectively extend outward from the two side surfaces of the lower insulating structure 120, which correspond to the two side surfaces of the first upper insulating layer 132. Accordingly, a horizontal length 130L of the first upper insulating layer 132 may be greater than a horizontal length 120L of the lower insulating structure 120. In embodiments, the horizontal length 130L of the first upper insulating layer 132 may be about 1.0 times to about 1.5 times the horizontal length 120L of the lower insulating structure 120. In embodiments, the horizontal length 130L of the first upper insulating layer 132 may be about 1.0 times to about 1.5 times a vertical height 130H of the upper insulating structure 130.

The second upper insulating layer 134 may be disposed on the first upper insulating layer 132. The second upper insulating layer 134 may have a tapered shape of which the horizontal length decreases in a direction from the lower insulating structure 120 toward the upper insulating structure 130 (i.e., upward in the vertical direction (the Z direction) in FIG. 1). That is, the second upper insulating layer 134 may include two side surfaces that form negative slopes from the lower surface of the second upper insulating layer 134. Accordingly, the distance between two upper insulating layers 134 horizontally adjacent to each other may gradually increase in the direction from the lower insulating structure 120 toward the upper insulating structure 130.

In embodiments, the first upper insulating layer 132 and the second upper insulating layer 134 may each include oxide. For example, the first upper insulating layer 132 and the second upper insulating layer 134 may each include AlO, ZrO, HfO, SiO₂, AlSiO, or a combination thereof.

In embodiments, the first upper insulating layer 132 may include a different material from the second upper insulating layer 134. For example, the first upper insulating layer 132 may include HfO, and the second upper insulating layer 134 may include AlO.

The upper insulating structure 130 and part of the metal wiring layer 122 may be covered by a second etch stop layer 142. The second etch stop layer 142 may include a silicon nitride layer, a carbon-doped silicon nitride layer, or a carbon-doped silicon oxynitride layer. In embodiments, the second etch stop layer 142 may include an insulating metal oxide layer, an insulating metal nitride layer, or a combination thereof. For example, the second etch stop layer 142 may include an aluminum oxide layer (an AlO layer), an aluminum nitride layer (an AlN layer), or a combination thereof.

An interlayer insulating layer 160 may be disposed on the second etch stop layer 142. The interlayer insulating layer 160 may cover the second etch stop layer 142. The interlayer insulating layer 160 may include, for example, an oxide layer.

The metal via 150 may pass through the second etch stop layer 142 and the interlayer insulating layer 160. The metal via 150 may be partially in contact with the upper surface of the metal wiring layer 122 and the upper insulating structure 130. The metal via 150 may electrically connect the metal wiring layer 122 to a wiring layer (not shown) located above the metal via 150. The metal via 150 may include a conductive liner 152 and a conductive layer 154. The conductive liner 152 may be in contact with the interlayer insulating layer 160 and the second etch stop layer 142. The conductive layer 154 may fill the inner space of the conductive liner 152. In the metal via 150, the conductive layer 154 may include Cu, W, Mo, Ru, Co, Al, or a combination thereof, and the conductive liner 152 may include a TiN layer, a TaN layer, a Co layer, or a combination thereof. However, the embodiments are not limited thereto.

The semiconductor device 100 according to embodiments includes the upper insulating structure 130 that includes the first upper insulating layer 132 and the second upper insulating layer 134 disposed on the first upper insulating layer 132. The horizontal length 130L of the first upper insulating layer 132 may be greater than the horizontal length 120L of the lower insulating structure 120, and the second upper insulating layer 134 may have the tapered shape having the negative slope from the lower surface of the second upper insulating layer 134. Accordingly, the distance between the two upper insulating structures 130 horizontally adjacent to each other gradually increases in the direction from the lower insulating structure 120 toward the upper insulating structure 130, and the metal via 150 located in the space between the two upper insulating structures 130 may have a sufficient horizontal width. Accordingly, the reliability of electrical connection via the metal via 150 may be improved.

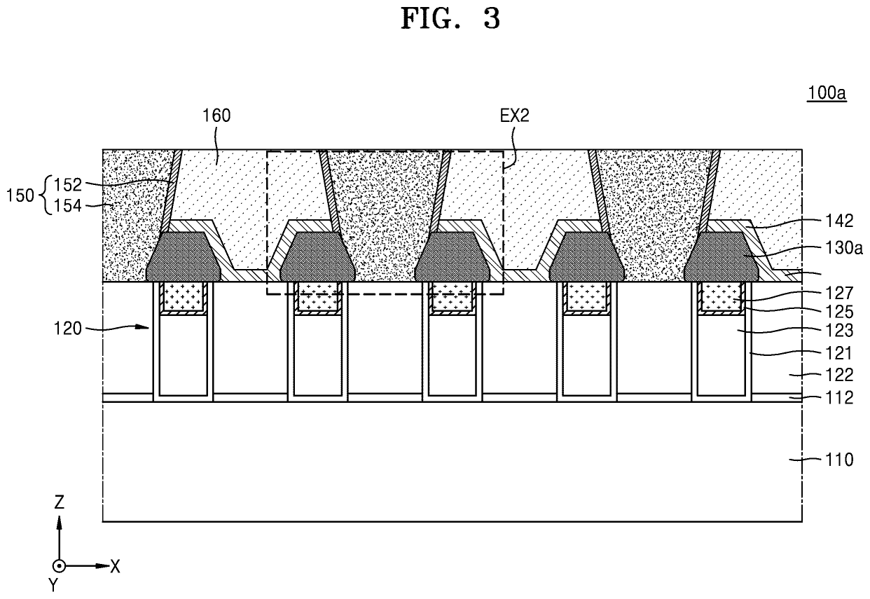

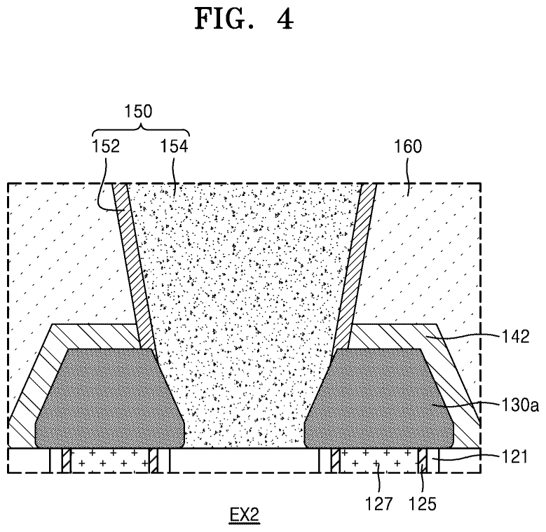

FIG. 3 is a cross-sectional view illustrating a semiconductor device 100a according to embodiments. FIG. 4 is an enlarged cross-sectional view of region EX2 of FIG. 3. Since components of the semiconductor device 100a shown in FIGS. 3 and 4 are substantially the same as or similar to components of the semiconductor device 100 described with reference to FIGS. 1 and 2, the description below focuses on the differences therebetween.

Referring to FIGS. 3 and 4, the semiconductor device 100a may be substantially the same as or similar to the semiconductor device 100 illustrated in FIGS. 1 and 2, except that the semiconductor device 100a includes an upper insulating structure 130a.

The semiconductor device 100a may include the upper insulating structure 130a disposed on the lower insulating structure 120. The upper insulating structure 130a may cover the upper surface of the lower insulating structure 120 and may cover the upper surface of part of the metal wiring layer 122, which is adjacent to the lower insulating structure 120. The upper insulating structure 130a may include a lower portion, which has a quadrangular shape of which both side surfaces are not inclined, and an upper portion, which is disposed on the lower portion. The two side surfaces of the lower portion of the upper insulating structure 130a may respectively extend outward from the two side surfaces of the lower insulating structure 120, which correspond to the two side surfaces of the lower portion of the upper insulating structure 130a. The upper portion of the upper insulating structure 130a may have a tapered shape having a side surface that forms a negative slope from the lower surface of the upper portion of the upper insulating structure 130a. The upper insulating structure 130a of the semiconductor device 100a may have a single material layer, unlike the upper insulating structure 130 of the semiconductor device 100 shown in FIGS. 1 and 2. For example, the upper insulating structure 130a of the semiconductor device 100a may include AlO, ZrO, HfO, SiO₂, AlSiO, or a combination thereof.

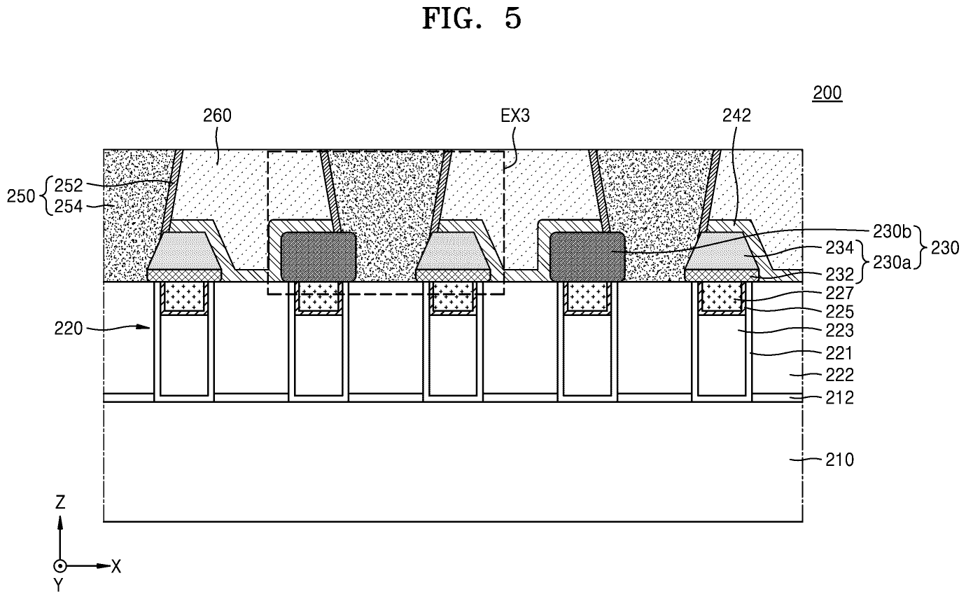

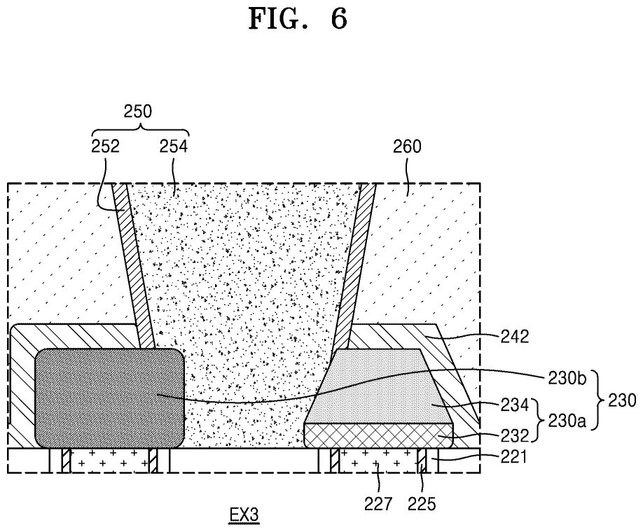

FIG. 5 is a cross-sectional view illustrating a semiconductor device 200 according to embodiments. FIG. 6 is an enlarged cross-sectional view of region EX3 of FIG. 5.

Referring to FIGS. 5 and 6, the semiconductor device 200 may include a substrate 210, a metal wiring layer 222 above the substrate 210, and a metal via 250 disposed on the metal wiring layer 222.

The semiconductor device 200 may represent, for example, a semiconductor device included in volatile memory or non-volatile memory.

The substrate 210 may have a structure substantially the same as or similar to that of the substrate 110 of the semiconductor device 100 shown in FIGS. 1 and 2 and may include a material substantially the same as or similar to that of the substrate 110.

A first etch stop layer 212 may be disposed on the substrate 210. A lower insulating structure 220 may pass through the first etch stop layer 212 in the vertical direction (the Z direction) and be disposed on the substrate 210. The metal wiring layer 222 may be disposed above the substrate 210. The first etch stop layer 212, the lower insulating structure 220, and the metal wiring layer 222 may have structures substantially the same as or similar to those of the first etch stop layer 112, the lower insulating structure 120, and the metal wiring layer 122, respectively, of the semiconductor device 100 shown in FIGS. 1 and 2 and may include materials substantially the same as or similar to those of the first etch stop layer 112, the lower insulating structure 120, and the metal wiring layer 122, respectively.

An upper insulating structure 230 may be disposed on the lower insulating structure 220. The upper insulating structure 230 may include a first upper insulating structure 230a and a second upper insulating structure 230b.

The first upper insulating structure 230a and the second upper insulating structure 230b may be horizontally spaced apart from each other with the metal via 250 therebetween, which is described below. The first upper insulating structure 230a and the second upper insulating structure 230b may each be in contact with the upper surface of the lower insulating structure 220. The first upper insulating structure 230a and the second upper insulating structure 230b may each cover the upper surface of the lower insulating structure 220 and cover the upper surface of part of the metal wiring layer 222, which is adjacent to the lower insulating structure 220. The horizontal length of the first upper insulating structure 230a and the horizontal length of the second upper insulating structure 230b may each be greater than the horizontal length of the lower insulating structure 220.

The first upper insulating structure 230a may include a first upper insulating layer 232 and a second upper insulating layer 234. The first upper insulating layer 232 may be disposed on the lower insulating structure 220 that corresponds to the first upper insulating structure 230a in the vertical direction (the Z direction) among lower insulating structures 220, and the second upper insulating layer 234 may be disposed on the first upper insulating layer 232. The first upper insulating layer 232 may have a quadrangular shape of which both side surfaces are not inclined. The two side surfaces of the first upper insulating layer 232 may respectively extend outward from the two side surfaces of the lower insulating structure 220, which correspond to the two side surfaces of the first upper insulating layer 232. The second upper insulating layer 234 may have a tapered shape of which the horizontal length decreases in a direction from the lower insulating structure 220 toward the first upper insulating structure 230a (i.e., upward in the vertical direction (the Z direction) in FIG. 1). That is, the second upper insulating layer 234 may include a side surface that forms a negative slope from the lower surface of the second upper insulating layer 234.

The second upper insulating structure 230b may be disposed on the lower insulating structure 220 that corresponds to the second upper insulating structure 230b in the vertical direction (the Z direction) among the lower insulating structures 220. The second upper insulating structure 230b may have a quadrangular shape with rounded corners. That is, the side surfaces of the second upper insulating structure 230b may not be inclined.

In embodiments, the first upper insulating layer 232, the second upper insulating layer 234, and the second upper insulating structure 230b may each include oxide. For example, the first upper insulating layer 232, the second upper insulating layer 234, and the second upper insulating structure 230b may each include AlO, ZrO, HfO, SiO₂, AlSiO, or a combination thereof.

In embodiments, the first upper insulating layer 232 may include a different material from the second upper insulating layer 234. For example, the first upper insulating layer 232 may include HfO, and the second upper insulating layer 234 may include AIO.

In embodiments, the second upper insulating structure 230b may have a single material layer. That is, the first upper insulating structure 230a may be provided as the first upper insulating layer 232 and the second upper insulating layer 234, which include different materials, but the second upper insulating structure 230b may be provided as a single layer.

In embodiments, the second upper insulating structure 230b may include the same material as either the first upper insulating layer 232 or the second upper insulating layer 234. For example, the second upper insulating structure 230b and the first upper insulating layer 232 may include HfO, and the second upper insulating layer 234 may include AlO.

In embodiments, the second upper insulating structure 230b may include a different material from the first upper insulating layer 232 and the second upper insulating layer 234. For example, the second upper insulating structure 230b may include SiO₂, the first upper insulating layer 232 may include HfO, and the second upper insulating layer 234 may include AlO.

The upper insulating structure 230 and part of the metal wiring layer 222 may be covered by a second etch stop layer 242. An interlayer insulating layer 260 may be disposed on the second etch stop layer 242. The metal via 250 may pass through the second etch stop layer 242 and the interlayer insulating layer 260. The second etch stop layer 242, the interlayer insulating layer 260, and the metal via 250 may have structures substantially the same as or similar to those of the second etch stop layer 142, the interlayer insulating layer 160, and the metal via 150, respectively, of the semiconductor device 100 shown in FIGS. 1 and 2 and may include materials substantially the same as or similar to those of the second etch stop layer 142, the interlayer insulating layer 160, and the metal via 150, respectively.

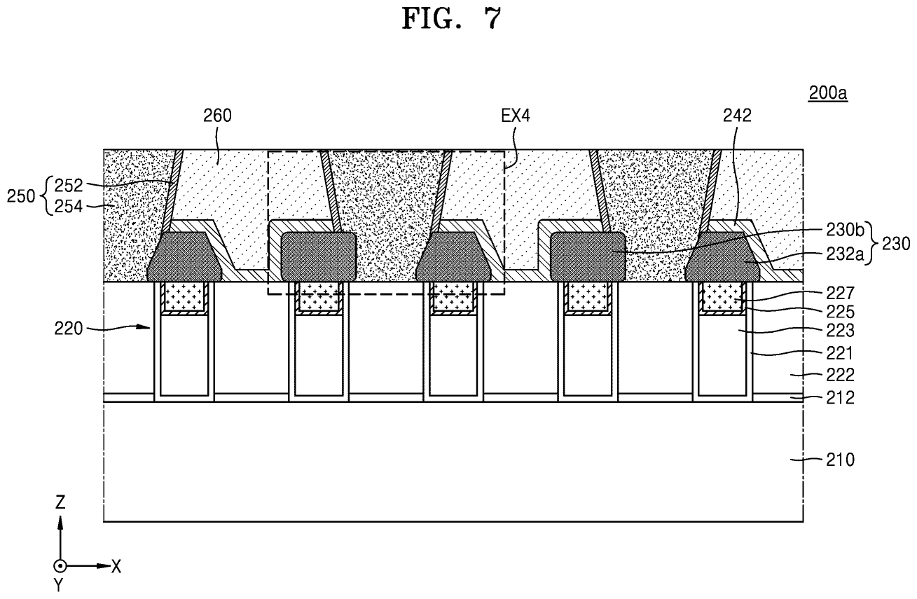

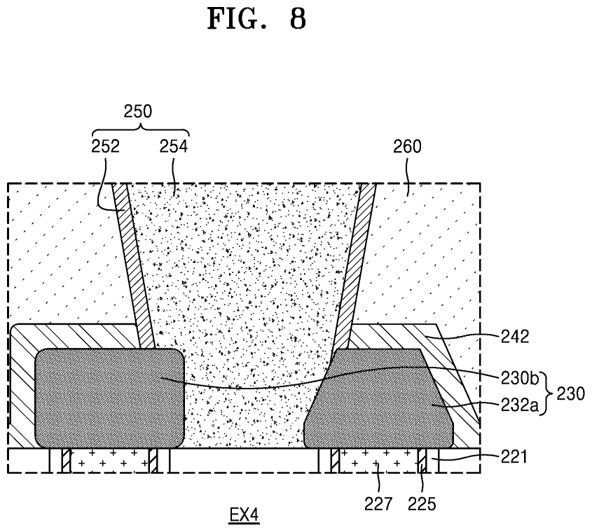

FIG. 7 is a cross-sectional view illustrating a semiconductor device 200a according to embodiments. FIG. 8 is an enlarged cross-sectional view of region EX4 of FIG. 7. Since components of the semiconductor device 200a shown in FIGS. 7 and 8 are substantially the same as or similar to components of the semiconductor device 200 described with reference to FIGS. 5 and 6, the description below focuses on the differences therebetween.

Referring to FIGS. 7 and 8, the semiconductor device 200a may be substantially the same as or similar to the semiconductor device 200 illustrated in FIGS. 5 and 6, except that the semiconductor device 200a includes a first upper insulating structure 232a.

The semiconductor device 200a may include the first upper insulating structure 232a and the second upper insulating structure 230b which are respectively disposed on the lower insulating structures 220. The second upper insulating structure 230b may be substantially the same as or similar to the second upper insulating structure 230b of the semiconductor device 200 shown in FIGS. 5 and 6. The first upper insulating structure 232a may include a lower portion, which has a quadrangular shape of which both side surfaces are not inclined, and an upper portion, which is disposed on the lower portion. The two side surfaces of the lower portion of the first upper insulating structure 232a may respectively extend outward from the two side surfaces of the lower insulating structure 220, which correspond to the two side surfaces of the lower portion of the first upper insulating structure 232a. The upper portion of the first upper insulating structure 232a may have a tapered shape having a side surface that forms a negative slope from the lower surface of the upper portion of the first upper insulating structure 232a.

The first upper insulating structure 232a of the semiconductor device 200a may have a single material layer, unlike the first upper insulating structure 230a of the semiconductor device 200 shown in FIGS. 5 and 6. For example, the first upper insulating structure 232a of the semiconductor device 200a may include AlO, ZrO, HfO, SiO₂, AlSiO, or a combination thereof.

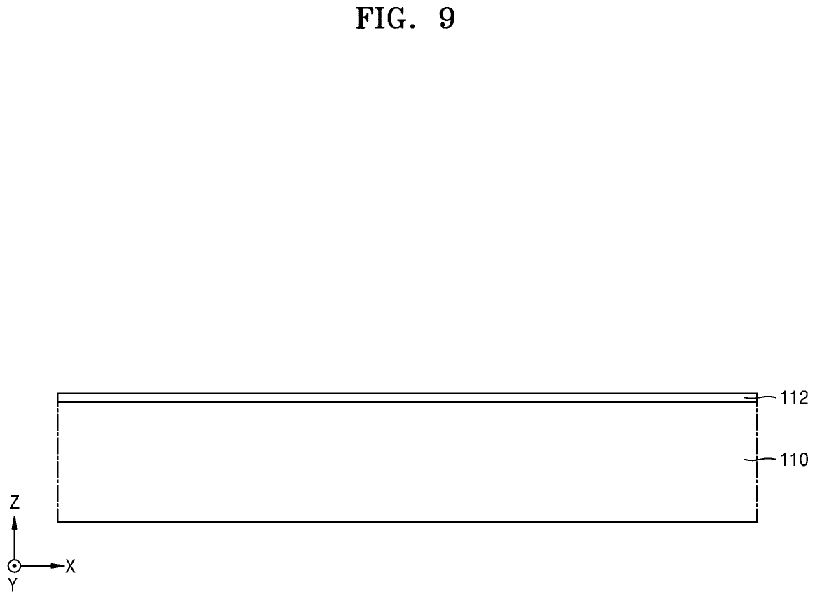

FIGS. 9 to 15 are cross-sectional views illustrating a method of manufacturing the semiconductor device 100, according to embodiments.

Referring to FIG. 9, the first etch stop layer 112 may be formed on the substrate 110 that has been provided. In an embodiment, the first etch stop layer 112 may be formed by performing a deposition process, for example, a physical vapor deposition (PVD) process, a chemical vapor deposition (CVD) process, or an atomic layer deposition (ALD) process, but the embodiment is not limited thereto. In an embodiment, the first etch stop layer 112 may include a silicon nitride layer, a carbon-doped silicon nitride layer, or a carbon-doped silicon oxynitride layer. In embodiments, the first etch stop layer 112 may include an insulating metal oxide layer, an insulating metal nitride layer, or a combination thereof. For example, the first etch stop layer 112 may include an aluminum oxide layer (an AlO layer), an aluminum nitride layer (an AlN layer), or a combination thereof.

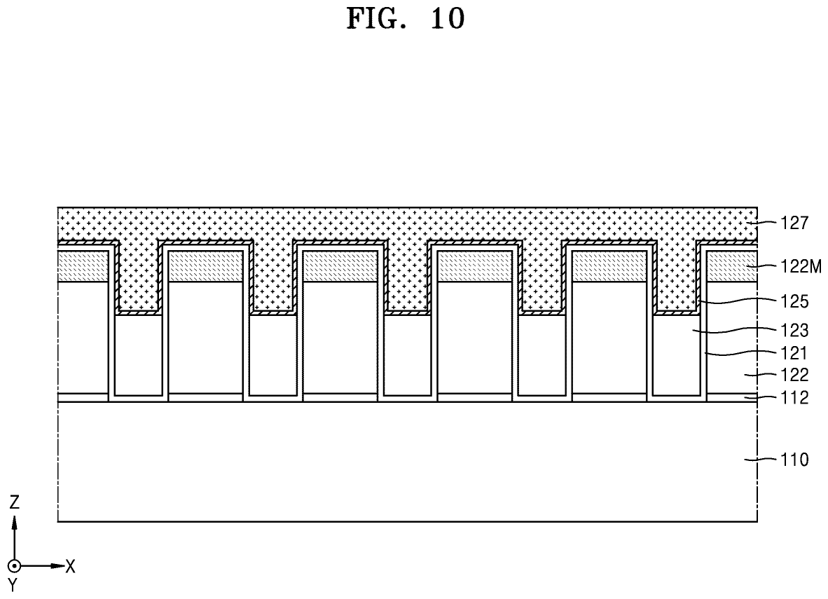

Referring to FIG. 10, the metal wiring layer 122 and a sacrificial layer 122M may be formed on the resulting structure of FIG. 9, and the metal wiring layer 122 and the sacrificial layer 122M may each be partially removed. Next, the first insulating liner 121, the first lower insulating layer 123, the second insulating liner 125, and the second lower insulating layer 127 may be sequentially formed. The first insulating liner 121 may cover a space, which is formed by partially removing the metal wiring layer 122 and the sacrificial layer 122M, and part of the sacrificial layer 122M, the first lower insulating layer 123 may partially fill the space described above, the second insulating liner 125 may cover the upper surface of the first lower insulating layer 123 and the inner wall of the first insulating liner 121, and the second lower insulating layer 127 may fill the inner space of the second insulating liner 125.

The metal wiring layer 122 and the sacrificial layer 122M may be removed, for example, by an etching process. The first insulating liner 121, the first lower insulating layer 123, the second insulating liner 125, and the second lower insulating layer 127 may be formed, for example, by a deposition process.

In embodiments, the metal wiring layer 122 may include, for example, Cu, W, Mo, Ru, Co, Al, or a combination thereof. In embodiments, the sacrificial layer 122M may include nitride. In embodiments, the first insulating liner 121 and the second insulating liner 125 may each include, but are not limited to, silicon oxide, silicon oxynitride, silicon nitride, a low-k material having a lower dielectric constant than silicon oxide, or a combination thereof. In embodiments, the first lower insulating layer 123 and the second lower insulating layer 127 may each include, but are not limited to, silicon oxide, silicon oxynitride, silicon nitride, a low-k material having a lower dielectric constant than silicon oxide, or a combination thereof.

In embodiments, the first lower insulating layer 123 may include an air gap. That is, the first lower insulating layer 123 may contain air.

The lower insulating structure 120 may be formed by the process described with reference to FIG. 10.

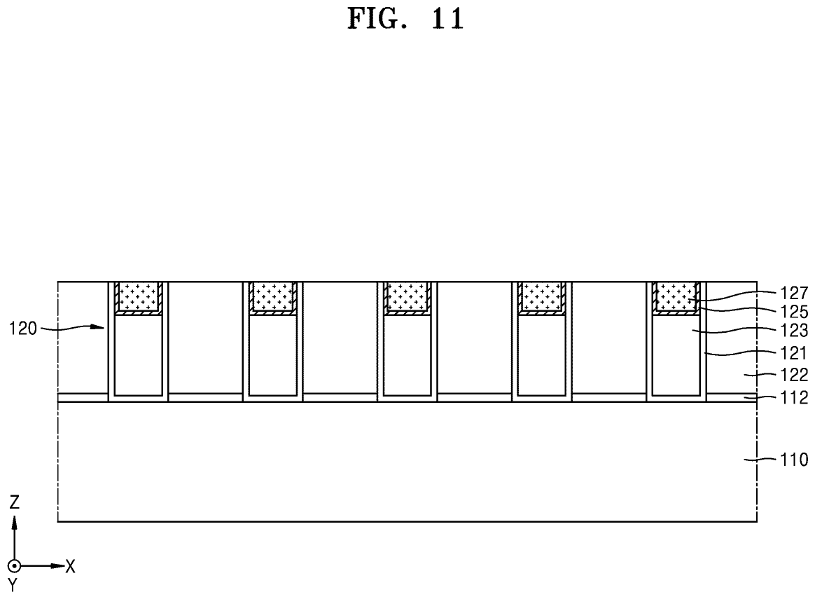

Referring to FIG. 11, a planarization process may be performed on the resulting structure of FIG. 10. The planarization process may include, for example, a chemical mechanical polishing (CMP) process. The planarization process may remove the sacrificial layer 122M (see FIG. 10) and partially remove the first insulating liner 121, the second insulating liner 125, and the second lower insulating layer 127. Also, the upper surface of each of the first insulating liner 121, the second insulating liner 125, the second lower insulating layer 127, and the metal wiring layer 122, which remain after the planarization process, may be exposed.

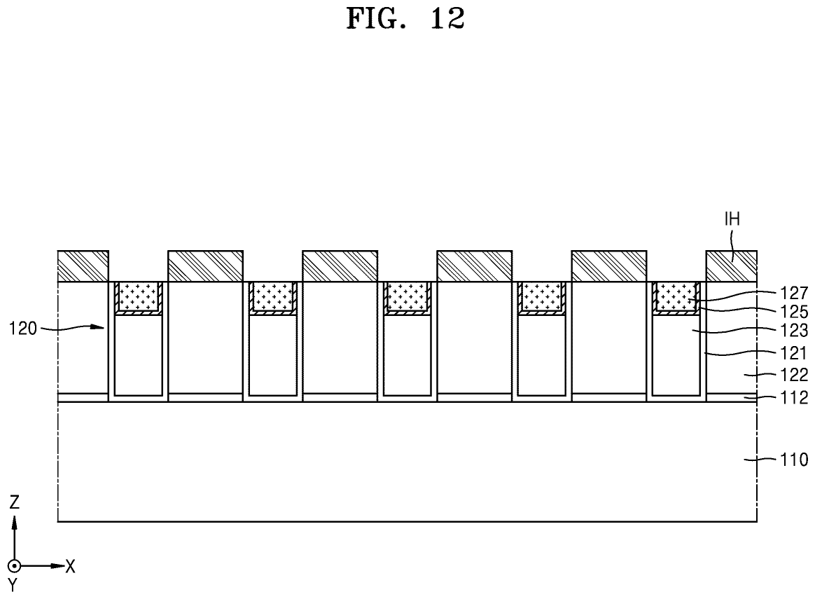

Referring to FIG. 12, an inhibitor IH may be formed on the metal wiring layer 122 in the resulting structure of FIG. 11. The inhibitor IH may cover the metal wiring layer 122, but may expose the upper surface of each of the first insulating liner 121, the second insulating liner 125, and the second lower insulating layer 127. The inhibitor IH may include a silicon (Si) precursor-type material, for example, bis(N, N-dimethylamino)dimethylsilane (DMADMS) or tri(dimethylamino)silane(TDMAS).

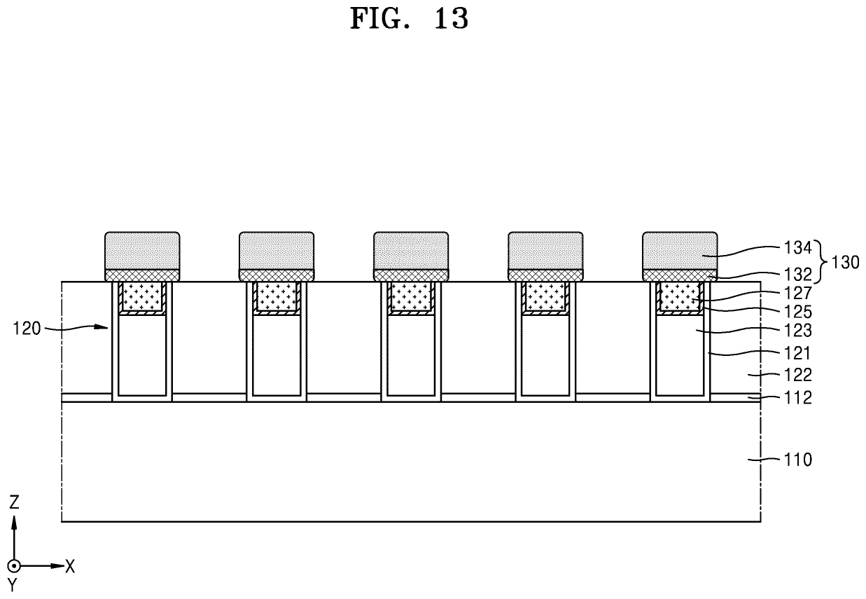

Referring to FIG. 13, in the resulting structure of FIG. 12, the upper insulating structures 130 each including the first upper insulating layer 132 and the second upper insulating layer 134 may be formed in the space between inhibitors IH (see FIG. 12) disposed on the metal wiring layer 122. The upper insulating structure 130 may be formed by, for example, depositing each of the first upper insulating layer 132 and the second upper insulating layer 134. In the deposition process, the first upper insulating layer 132 and the second upper insulating layer 134 may be laterally grown. Accordingly, the horizontal length of each of the first upper insulating layer 132 and the second upper insulating layer 134 may be greater than the horizontal length of the lower insulating structure 120.

In embodiments, the first upper insulating layer 132 and the second upper insulating layer 134 may each include oxide. For example, the first upper insulating layer 132 and the second upper insulating layer 134 may each include AlO, ZrO, HfO, SiO₂, AlSiO, or a combination thereof. In embodiments, the first upper insulating layer 132 may include a different material from the second upper insulating layer 134. For example, the first upper insulating layer 132 may include HfO, and the second upper insulating layer 134 may include AlO.

In embodiments, unlike the process described with reference to FIG. 13, the upper insulating structure may be formed as a single layer. In this case, by performing the process described below, the semiconductor device 100a shown in FIGS. 3 and 4 may be manufactured.

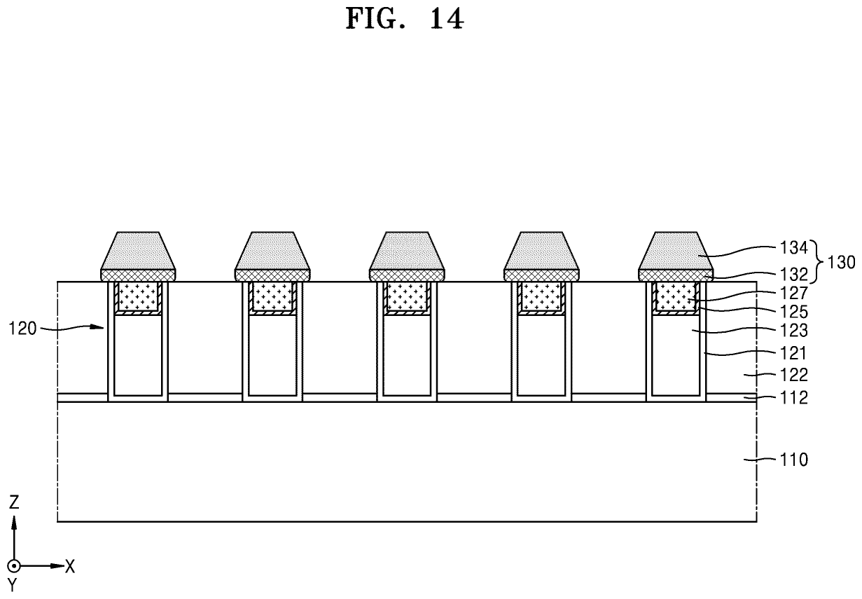

Also, in embodiments, the upper insulating structure is formed as a single layer as described above. Subsequently, unlike the process described with reference to FIG. 14, only part of the side surfaces of one of the two upper insulating structures adjacent to each other may be removed, and the side surfaces of the other upper insulating structure may not be removed. In this case, by performing the processes described below, the semiconductor device 200a shown in FIGS. 7 and 8 may be manufactured.

Referring to FIG. 14, in the resulting structure of FIG. 13, the side surfaces of the second upper insulating layer 134 may be partially removed. The side surfaces of the second upper insulating layer 134 may be partially removed, for example, by an etching process. Through the etching process, the second upper insulating layer 134 may have a tapered shape of which the horizontal length decreases in a direction from the lower insulating structure 120 toward the upper insulating structure 130 (i.e., upward in the vertical direction (the Z direction) in FIG. 14). That is, the second upper insulating layer 134 may include the side surface that forms a negative slope from the lower surface of the second upper insulating layer 134.

In embodiments, unlike the process described with reference to FIG. 14, only part of the side surfaces of the second upper insulating layer 134 of one of the two upper insulating structures 130 adjacent to each other may be removed, and the side surfaces of the second upper insulating layer 134 of the other upper insulating structure 130 may not be removed. In this case, by performing the processes described below, the semiconductor device 200 shown in FIGS. 5 and 6 may be manufactured.

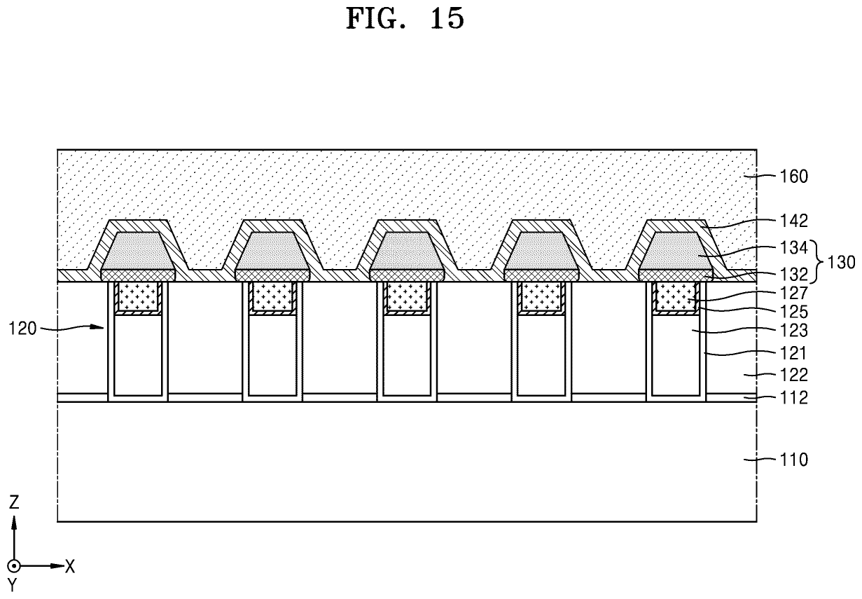

Referring to FIG. 15, in the resulting structure of FIG. 14, the second etch stop layer 142 may be formed to cover the upper insulating structure 130 and the metal wiring layer 122, and the interlayer insulating layer 160 may be formed to cover the second etch stop layer 142. In embodiments, the second etch stop layer 142 may include a silicon nitride layer, a carbon-doped silicon nitride layer, or a carbon-doped silicon oxynitride layer. In embodiments, the second etch stop layer 142 may include an insulating metal oxide layer, an insulating metal nitride layer, or a combination thereof. For example, the second etch stop layer 142 may include an aluminum oxide layer (an AlO layer), an aluminum nitride layer (an AlN layer), or a combination thereof. In embodiments, the interlayer insulating layer 160 may include an oxide layer.

Next, in the resulting structure of FIG. 15, the metal via 150 (see FIG. 1) may be formed so as to pass through the second etch stop layer 142 and the interlayer insulating layer 160 in the vertical direction (the Z direction). The metal via 150 may be partially in contact with the upper surface of the metal wiring layer 122 and the upper insulating structure 130. As the metal via 150 is formed, the semiconductor device 100 shown in FIGS. 1 and 2 may be completely manufactured.

While the inventive concept has been particularly shown and described with reference to embodiments thereof, it will be understood that various changes in form and details may be made therein without departing from the spirit and scope of the following claims.

What is claimed is:

1. A semiconductor device comprising:
a substrate;
a metal wiring layer disposed above the substrate;
a lower insulating structure disposed on the substrate and in contact with the metal wiring layer;
an upper insulating structure disposed on the lower insulating structure; and
a metal via disposed on the metal wiring layer and connected to the metal wiring layer,
wherein the upper insulating structure extends outward from both side surfaces of the lower insulating structure, and a side surface of the upper insulating structure has a negative slope from a lower surface of the upper insulating structure.

2. The semiconductor device of claim 1, wherein the upper insulating structure comprises a first upper insulating layer disposed on the lower insulating structure and a second upper insulating layer disposed on the first upper insulating layer, and
the first upper insulating layer has a quadrangular shape, and the second upper insulating layer has a tapered shape of which both side surfaces have a negative slope.

3. The semiconductor device of claim 2, wherein the first upper insulating layer and the second upper insulating layer each comprise AlO, ZrO, HfO, SiO₂, AlSiO, or a combination thereof.

4. The semiconductor device of claim 2, wherein the first upper insulating layer comprises a different material from a material of the second upper insulating layer.

5. The semiconductor device of claim 2, wherein the first upper insulating layer comprises a same material as a material of the second upper insulating layer.

6. The semiconductor device of claim 1, wherein a horizontal length of the upper insulating structure is about 1.0 times to about 1.5 times a horizontal length of the lower insulating structure.

7. The semiconductor device of claim 1, wherein the upper insulating structure is formed as a single layer comprising AlO, ZrO, HfO, SiO₂, AlSiO, or a combination thereof.

8. The semiconductor device of claim 1, wherein the upper insulating structure comprises a first upper insulating structure and a second upper insulating structure spaced apart from each other with one metal via therebetween, and
the first upper insulating structure has a tapered shape of which a side surface has a negative slope, and the second upper insulating structure has a quadrangular shape.

9. The semiconductor device of claim 8, wherein the first upper insulating structure comprises a first upper insulating layer and a second upper insulating layer disposed on the first upper insulating layer, and the first upper insulating layer and the second upper insulating layer each comprise AlO, ZrO, HfO, SiO₂, AlSiO, or a combination thereof.

10. The semiconductor device of claim 9, wherein the first upper insulating layer comprises a different material from a material of the second upper insulating layer.

11. The semiconductor device of claim 9, wherein the first upper insulating layer comprises a same material as a material of the second upper insulating layer.

12. The semiconductor device of claim 8, wherein the second upper insulating structure is formed as a single layer comprising AlO, ZrO, HfO, SiO₂, AlSiO, or a combination thereof.

13. A semiconductor device comprising:
a substrate;
a metal wiring layer disposed above the substrate;
a lower insulating structure disposed on the substrate and in contact with the metal wiring layer;
an upper insulating structure disposed on the lower insulating structure; and
a metal via disposed on the metal wiring layer and connected to the metal wiring layer,
wherein the upper insulating structure comprises a first upper insulating layer disposed on the lower insulating structure and a second upper insulating layer disposed on the first upper insulating layer,
the first upper insulating layer has a quadrangular shape of which side surfaces extend outward from both side surfaces of the lower insulating structure, and the second upper insulating layer has a tapered shape of which a side surface has a negative slope from a lower surface of the upper insulating structure.

14. The semiconductor device of claim 13, wherein the first upper insulating layer and the second upper insulating layer each comprise AlO, ZrO, HfO, SiO₂, AlSiO, or a combination thereof, and the first upper insulating layer comprises a different material from the second upper insulating layer.

15. The semiconductor device of claim 13, wherein the first upper insulating layer comprises a same material as a material of the second upper insulating layer.

16. The semiconductor device of claim 13, wherein a horizontal length of the upper insulating structure is about 1.0 times to about 1.5 times a horizontal length of the lower insulating structure.

17. The semiconductor device of claim 13, wherein a horizontal length of the upper insulating structure is about 1.0 times to about 1.5 times a vertical height of the upper insulating structure.

18. A semiconductor device comprising:
a substrate;
a first etch stop layer disposed on the substrate;
a metal wiring layer disposed on the first etch stop layer;
a lower insulating structure passing through the first etch stop layer and disposed on the substrate while being in contact with a side surface of the metal wiring layer;
an upper insulating structure disposed on the lower insulating structure;
a second etch stop layer covering a surface of the upper insulating structure and an upper surface of the metal wiring layer; and
a metal via passing through the second etch stop layer and disposed on the metal wiring layer, the metal via comprising a conductive liner and a conductive layer filling an inner space of the conductive liner,
wherein the upper insulating structure comprises a first upper insulating layer disposed on the lower insulating structure and a second upper insulating layer disposed on the first upper insulating layer,
the first upper insulating layer has a quadrangular shape of which side surfaces extend outward from both side surfaces of the lower insulating structure, and the second upper insulating layer has a tapered shape of which a side surface has a negative slope from a lower surface of the upper insulating structure.

19. The semiconductor device of claim 18, wherein the upper insulating structure completely covers an upper surface of the lower insulating structure and partially covers the metal wiring layer adjacent to the lower insulating structure.

20. The semiconductor device of claim 18, wherein the lower insulating structure comprises a first insulating liner, a first lower insulating layer filling an inner space of the first insulating liner, a second insulating liner disposed on the first lower insulating layer and in contact with an inner wall of the first insulating liner, and a second lower insulating layer filling an inner space of the second insulating liner, wherein the first lower insulating layer comprises an air gap.
